(19) United States
(12) Patent Application Publication
(10) Pub. No.: US 2015/0071463 A1
(43) Pub. Date: Mar. 12, 2015

(54) METHOD AND APPARATUS FOR FILTERING AN AUDIO SIGNAL

(71) Applicants: Riitta Elina Niemistö, Tampere (FI); Jorma Mäkinen, Tampere (FI)

(72) Inventors: Riitta Elina Niemistö, Tampere (FI); Jorma Mäkinen, Tampere (FI)

(73) Assignee: Nokia Corporation, Espoo (FI)

(21) Appl. No.: 14/386,000

(22) PCT Filed: Mar. 30, 2012
(86) PCT No.: PCT/FI2012/050320

§ 371 Date: Sep. 18, 2014

(51) Int. Cl. H03G 3/34

(52) U.S. Cl. CPC H03G 3/348
USPC 381/94.5

(57) ABSTRACT

It is inter alia disclosed to determine a peak energy level for an audio frame of a band limited audio signal; determine that the peak energy level is a maximum peak energy level by determining that the peak energy level exceeds a peak energy level determined for at least one neighboring audio frame by a first predetermined energy threshold value; classify a region of audio samples associated with the maximum peak energy level as an audio click; and suppress audio samples of the region of audio samples classified as an audio click by multiplying at least one audio sample of the audio frame with a sample wise suppressor gain function.

### FIELD OF THE APPLICATION

The present application relates to apparatus for the processing of audio signals. The application further relates to, but is not limited to, apparatus for recording and processing audio signals.

### BACKGROUND OF THE APPLICATION

Electronic apparatus and in particular mobile or portable electronic apparatus may be equipped with integral microphone apparatus or suitable audio inputs for receiving a microphone signal. This permits the capture and processing of suitable audio signals for processing, encoding, storing, or transmitting to further devices. For example cellular telephones may have microphone apparatus configured to generate an audio signal in a format suitable for processing and transmitting via the cellular communications network to a further device, the signal at the further device may then be decoded and passed to a suitable listening apparatus such as a headphone or loudspeaker. Similarly some multimedia devices are equipped with mono or stereo microphone apparatus for audio capture of events for later playback or transmission.

The electronic apparatus can further comprise audio capture apparatus which either includes the microphone apparatus or receives the audio signals from one or more microphones and may perform some pre-encoding processing to reduce noise. For example the analogue signal may be converted to a digital format for further processing.

This pre-processing may be required when attempting to record full spectral band audio signals from a far audio signal source when the desired signals may be subjected to sporadic audio distortions such as such as pops and clicks.

A typical source of such sporadic audio distortion may be the sound of a camera shutter or the sound of an auto focussing system whilst a video recording is being made. Such distortions are easily picked up microphones embedded within the device before being converted to a digital audio signal by an analogue to digital converter.

In order to improve the quality of a digital audio signal before recording or any further processing is commenced it is desirable to remove all such sporadic audio distortions.

Known audio click suppression techniques typically deploy a multistage approach whereby a first stage may detect the click, and then a further stage determines a gain which may be applied to a section of audio signal to attenuate the audio click or pop. However, current approaches adopting multistage stage techniques can distort the section of the audio signal comprising the audio click, as well as providing insufficient attenuation of the audio click.

### SUMMARY OF THE APPLICATION

This application proceeds from the consideration that audio click suppression can deploy a two stage approach, whereby the first stage detects the audio click and the second stage suppresses the audio click. However, such techniques under certain conditions can result in both distortion of the audio signal and insufficient attenuation of the audio click. It is desirable therefore that an audio click suppression system sufficiently attenuates the audio click whilst subjecting the audio signal to a small amount of distortion as possible.

The following embodiments aim to address the above problem.

There is provided according to an aspect of the invention a method comprising determining a peak energy level for an audio frame of a band limited audio signal; determining that the peak energy level is a maximum peak energy level by determining that the peak energy level exceeds a peak energy level determined for at least one neighboring audio frame by a first predetermined energy threshold value; classifying a region of audio samples associated with the maximum peak energy level as an audio click; and suppressing audio samples of the region of audio samples classified as an audio click by multiplying at least one audio sample of the audio frame with a sample wise suppressor gain function.

The sample wise suppressor gain function for the at least one sample of the audio frame may be dependent at least in part upon a ratio of a determined long term tracked signal amplitude value for the audio frame and a sample wise signal amplitude value for the at least one sample of the audio frame.

The sample wise signal amplitude value for the at least one sample of the audio frame may be dependent on the maximum sample value of a plurality of samples encompassing the at least one sample of the audio frame.

The determined long term tracked signal amplitude value for the audio frame may be updated on an audio frame by audio frame basis and can be dependent on the combination of a past long term tracked signal amplitude value and a mean absolute amplitude value for the audio frame.

The determining that the peak energy is a maximum peak energy level further comprises: determining that the peak energy level of the audio frame may be within a second predetermined energy threshold value of an estimated maximum peak energy level for the audio frame.

The estimated maximum peak energy level may preferably be determined by: weighting a past estimated maximum peak energy level with a first weighting factor; weighting a maximum peak energy level for a previous audio frame with a second weighting factor; and combining the weighted past estimated maximum peak energy level with the weighted maximum peak energy level for the previous audio frame, wherein the first and second weighting factors can control the rate of adaptation of the estimated maximum peak energy level to the peak energy level of the audio frame.

The determining that the peak energy level is a maximum peak energy level may preferably further comprises determining a signal energy level for the audio frame, wherein the signal energy level is a minimum of the at least one peak energy level determined for the audio frame and the at least one neighboring audio frame; comparing the signal energy level for the audio frame to the estimated maximum peak energy level; and determining that the estimated maximum peak energy level exceeds the signal level by a third predetermined energy threshold value.

The determining the peak energy level for the audio frame of the band limited audio signal may preferably comprise: determining an energy value for a plurality of consecutive audio samples encompassed within the audio frame; determining a further energy value of a further plurality of consecutive audio samples within the audio frame, wherein the plurality of consecutive audio samples and the further plurality of consecutive audio samples overlap within the audio frame; and selecting the peak energy level for the audio frame to be the maximum of the energy value and the further energy value.

The determining that the peak energy level is a maximum peak energy level may preferably further comprise: determining a minimum signal level for the audio frame; and determining that the peak energy level for the audio frame exceeds the minimum signal level for the audio frame by an amount which is below a fourth predetermined energy threshold value.

Determining the minimum signal level for the audio frame may preferably comprise: determining an energy value for a plurality of consecutive audio samples encompassed within the audio frame; determining a further energy value of a further plurality of consecutive audio samples within the audio frame, wherein the plurality of consecutive audio samples and the further plurality of consecutive audio samples may overlap within the audio frame; and selecting the minimum signal level for the audio frame to be the minimum of the energy value and the further energy value.

The sample wise suppressor gain function applied to the at least one audio sample may be applied to at least one sample of a sub band audio signal of the band limited audio signal.

According to a further aspect there is provided an apparatus comprising at least one processor and at least one memory including computer code for one or more programs, the at least one memory and the computer code configured with the at least one processor to cause the apparatus to: determine a peak energy level for an audio frame of a band limited audio signal; determine that the peak energy level is a maximum peak energy level by determining that the peak energy level exceeds a peak energy level determined for at least one neighboring audio frame by a first predetermined energy threshold value; classify a region of audio samples associated with the maximum peak energy level as an audio click; and suppress audio samples of the region of audio samples classified as an audio click by multiplying at least one audio sample of the audio frame with a sample wise suppressor gain function.

The sample wise suppressor gain function for the at least one sample of the audio frame may be dependent at least in part upon a ratio of a determined long term tracked signal amplitude value for the audio frame and a sample wise signal amplitude value for the at least one sample of the audio frame.

The sample wise signal amplitude value for the at least one sample of the audio frame may be dependent on the maximum sample value of a plurality of samples encompassing the at least one sample of the audio frame.

The determined long term tracked signal amplitude value for the audio frame may be updated on an audio frame by audio frame basis and may be dependent on the combination of a past long term tracked signal amplitude value and a mean absolute amplitude value for the audio frame.

The at least one memory and the computer code configured to with the at least one processor cause the apparatus to determine that the peak energy is a maximum peak energy level may be further configured to cause the apparatus to determine that the peak energy level of the audio frame may be within a second predetermined energy threshold value of an estimated maximum peak energy level for the audio frame,

The estimated maximum peak energy level may be determined by causing the apparatus to: weight a past estimated maximum peak energy level with a first weighting factor; weight a maximum peak energy level for a previous audio frame with a second weighting factor; and combine the weighted past estimated maximum peak energy level with the weighted maximum peak energy level for the previous audio frame, wherein the first and second weighting factors control the rate of adaptation of the estimated maximum peak energy level to the peak energy level of the audio frame.

The at least one memory and the computer code configured with the at least one processor to cause the apparatus to determine that the peak energy level is a maximum peak energy level further comprises level may be further configured to cause the apparatus to: determine a signal energy level for the audio frame, wherein the signal energy level is a minimum of the at least one peak energy level determined for the audio frame and the at least one neighboring audio frame; compare the signal energy level for the audio frame to the estimated maximum peak energy level; and determine that the estimated maximum peak energy level exceeds the signal level by a third predetermined energy threshold value.

The at least one memory and the computer code configured with the at least one processor to cause the apparatus to determine that the peak energy level for the audio frame of the band limited audio signal may be further configured to cause the apparatus to: determine an energy value for a plurality of consecutive audio samples encompassed within the audio frame; determine a further energy value of a further plurality of consecutive audio samples within the audio frame, wherein the plurality of consecutive audio samples and the further plurality of consecutive audio samples overlap within the audio frame; and select the peak energy level for the audio frame to be the maximum of the energy value and the further energy value.

The at least one memory and the computer code configured with the at least one processor to cause the apparatus to determine that the peak energy level is a maximum peak energy level may be further configured to cause the apparatus to: determine a minimum signal level for the audio frame; and determine that the peak energy level for the audio frame exceeds the minimum signal level for the audio frame by an amount which is below a fourth predetermined energy threshold value.

The at least one memory and the computer code configured with the at least one processor to cause the apparatus to determine the minimum signal level for the audio frame may be further configured to cause the apparatus to: determine an energy value for a plurality of consecutive audio samples encompassed within the audio frame; determine a further energy value of a further plurality of consecutive audio samples within the audio frame, wherein the plurality of consecutive audio samples and the further plurality of consecutive audio samples overlap within the audio frame; and select the minimum signal level for the audio frame to be the minimum of the energy value and the further energy value.

The sample wise suppressor gain function applied to the at least one audio sample is applied to at least one sample of a sub band audio signal of the band limited audio signal.

According to a further aspect there is provided an apparatus comprising: means for determining a peak energy level for an audio frame of a band limited audio signal; means for determining that the peak energy level is a maximum peak energy level by determining that the peak energy level exceeds a peak energy level determined for at least one neighboring audio frame by a first predetermined energy threshold value; means for classifying a region of audio samples associated with the maximum peak energy level as an audio click; and means for suppressing audio samples of the region of audio samples classified as an audio click by multiplying at least one audio sample of the audio frame with a sample wise suppressor gain function.

The sample wise suppressor gain function for the at least one sample of the audio frame may be dependent at least in part upon a ratio of a determined long term tracked signal amplitude value for the audio frame and a sample wise signal amplitude value for the at least one sample of the audio frame.

The sample wise signal amplitude value for the at least one sample of the audio frame may be dependent on the maximum sample value of a plurality of samples encompassing the at least one sample of the audio frame.

The determined long term tracked signal amplitude value for the audio frame may be updated on an audio frame by audio frame basis and may be dependent on the combination of a past long term tracked signal amplitude value and a mean absolute amplitude value for the audio frame.

The means for determining that the peak energy is a maximum peak energy level may further comprise: means for determining that the peak energy level of the audio frame is within a second predetermined energy threshold value of an estimated maximum peak energy level for the audio frame,

The estimated maximum peak energy level may be determined by: weighting a past estimated maximum peak energy level with a first weighting factor; weighting a maximum peak energy level for a previous audio frame with a second weighting factor; and combining the weighted past estimated maximum peak energy level with the weighted maximum peak energy level for the previous audio frame, wherein the first and second weighting factors control the rate of adaptation of the estimated maximum peak energy level to the peak energy level of the audio frame.

The means for determining that the peak energy level is a maximum peak energy level may further comprise: means for determining a signal energy level for the audio frame, wherein the signal energy level is a minimum of the at least one peak energy level determined for the audio frame and the at least one neighboring audio frame; means for comparing the signal energy level for the audio frame to the estimated maximum peak energy level; and means for determining that the estimated maximum peak energy level exceeds the signal level by a third predetermined energy threshold value.

The means for determining the peak energy level for the audio frame of the band limited audio signal may comprise: means for determining an energy value for a plurality of consecutive audio samples encompassed within the audio frame; means for determining a further energy value of a further plurality of consecutive audio samples within the audio frame, wherein the plurality of consecutive audio samples and the further plurality of consecutive audio samples overlap within the audio frame; and means for selecting the peak energy level for the audio frame to be the maximum of the energy value and the further energy value.

The means for determining that the peak energy level is a maximum peak energy level may further comprises: means for determining a minimum signal level for the audio frame; and means for determining that the peak energy level for the audio frame exceeds the minimum signal level for the audio frame by an amount which is below a fourth predetermined energy threshold value.

The means for determining the minimum signal level for the audio frame may comprise: means for determining an energy value for a plurality of consecutive audio samples encompassed within the audio frame; means for determining a further energy value of a further plurality of consecutive audio samples within the audio frame, wherein the plurality of consecutive audio samples and the further plurality of consecutive audio samples overlap within the audio frame; and means for selecting the minimum signal level for the audio frame to be the minimum of the energy value and the further energy value.

The sample wise suppressor gain function applied to the at least one audio sample may be applied to at least one sample of a sub band audio signal of the band limited audio signal.

A computer readable medium comprising a computer program code thereon, the computer program code configured to realize the actions of the method as discussed herein.

An electronic device comprising an apparatus as discussed herein.

A chipset comprising an apparatus as discussed herein.

For better understanding of the present invention, reference will now be made by way of example to the accompanying drawings in which:

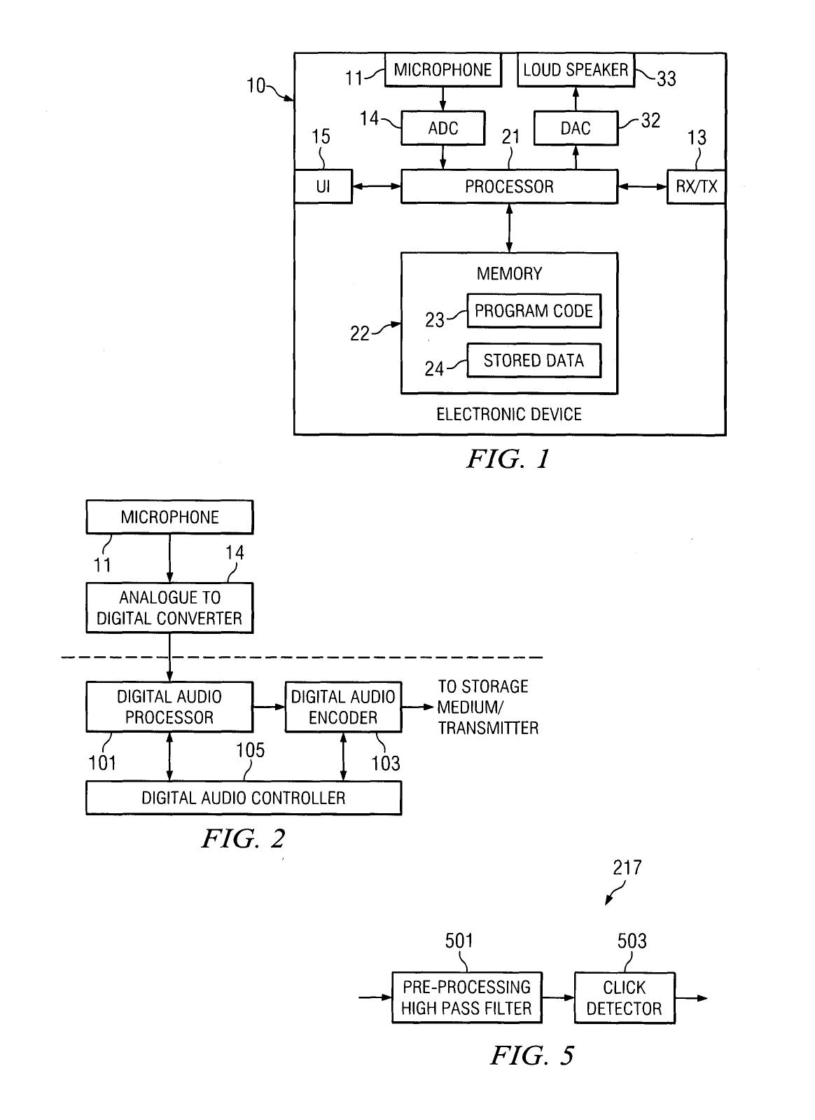

FIG. 1 shows schematically an electronic device employing embodiments of the invention;

FIG. 2 shows schematically an audio capture system employing embodiments of the present invention;

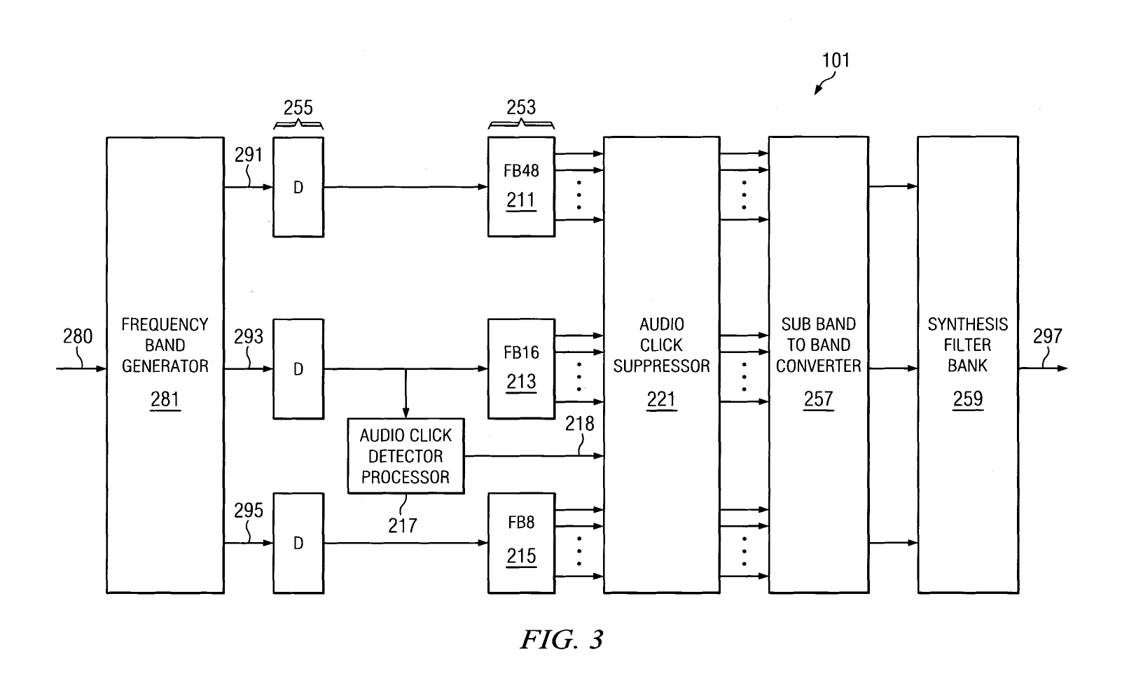

FIG. 3 shows schematically an audio capture digital processor according to some embodiments of the invention;

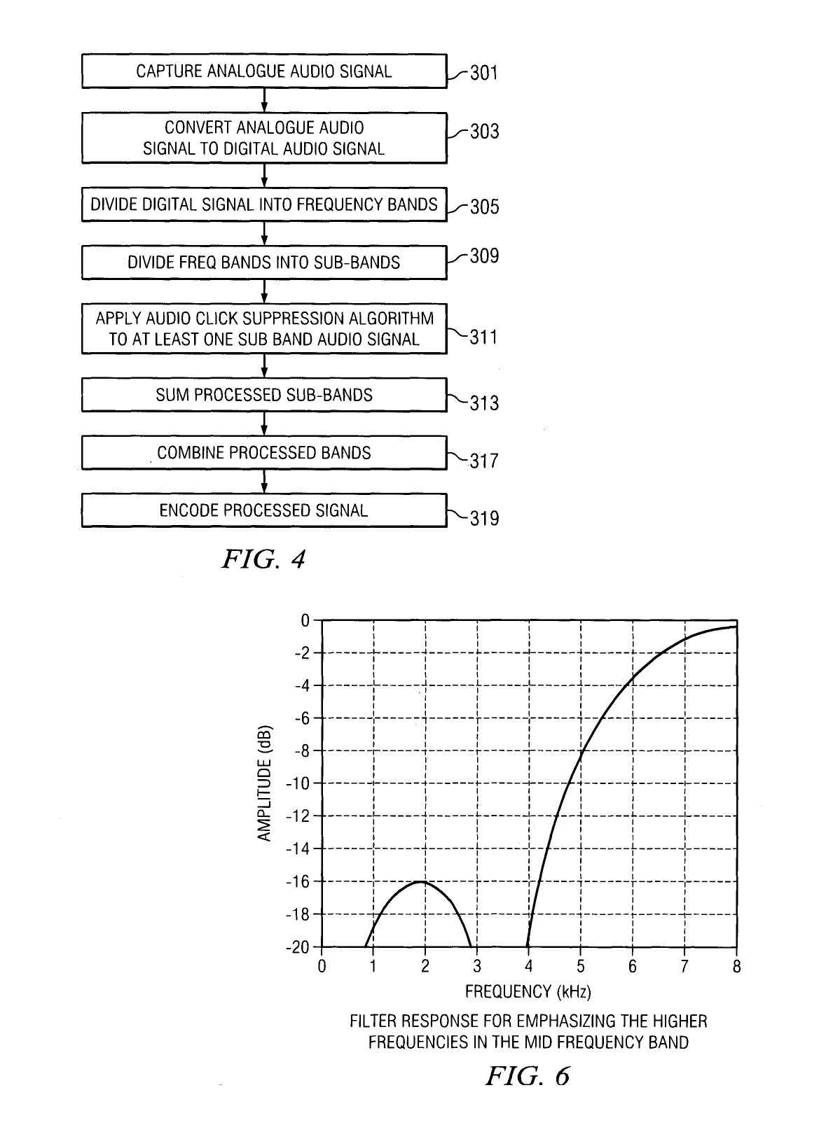

FIG. 4 shows a flow diagram illustrating the operation of the audio capture digital processor according to embodiments of the invention;

FIG. 5 shows schematically an audio click detector according to some embodiments of the invention;

FIG. 6 shows schematically a amplitude spectrum of the pre-processing high pass filter response according to embodiments of the invention;

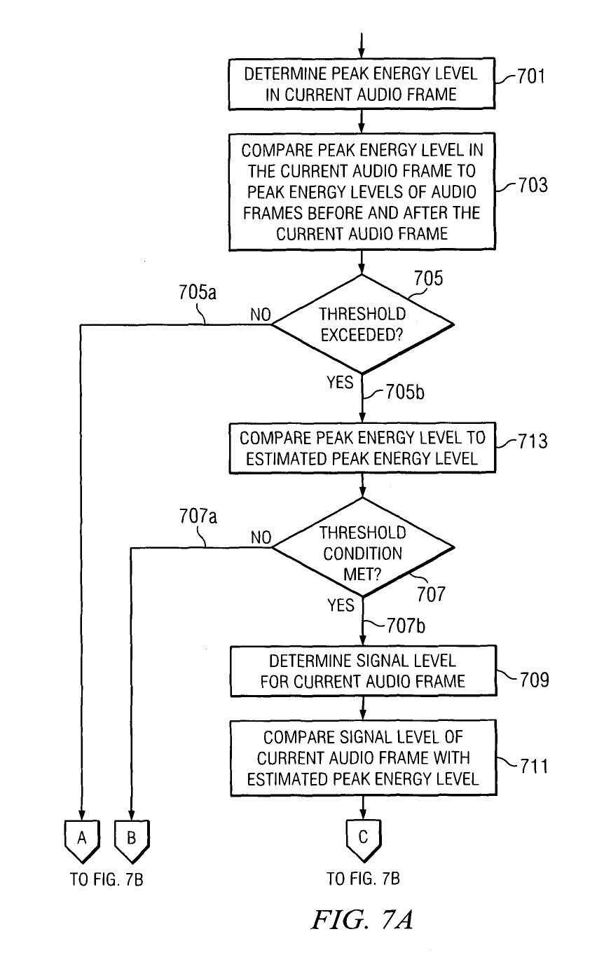

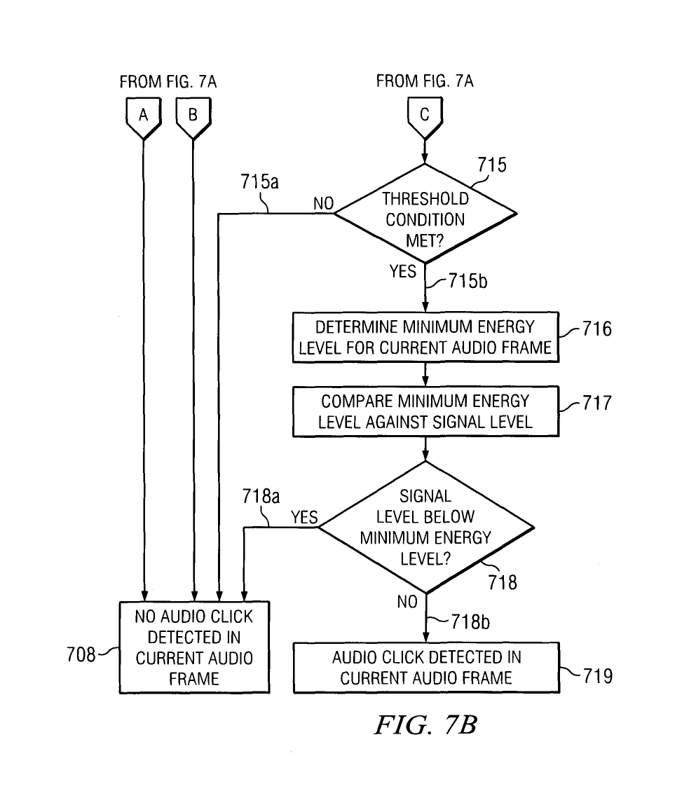

FIG. 7 shows a flow diagram illustrating the operation of the click detector according to embodiments of the invention;

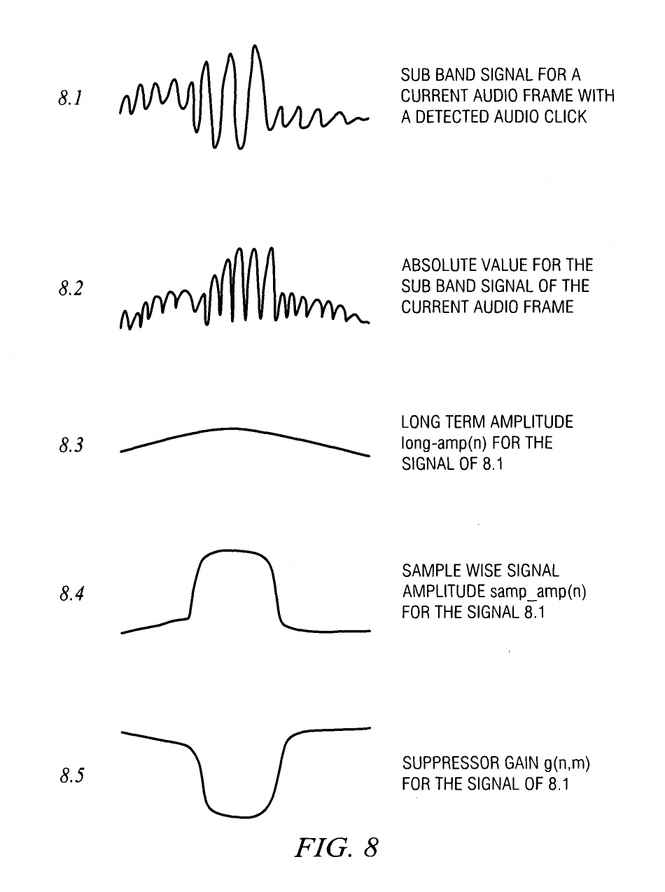

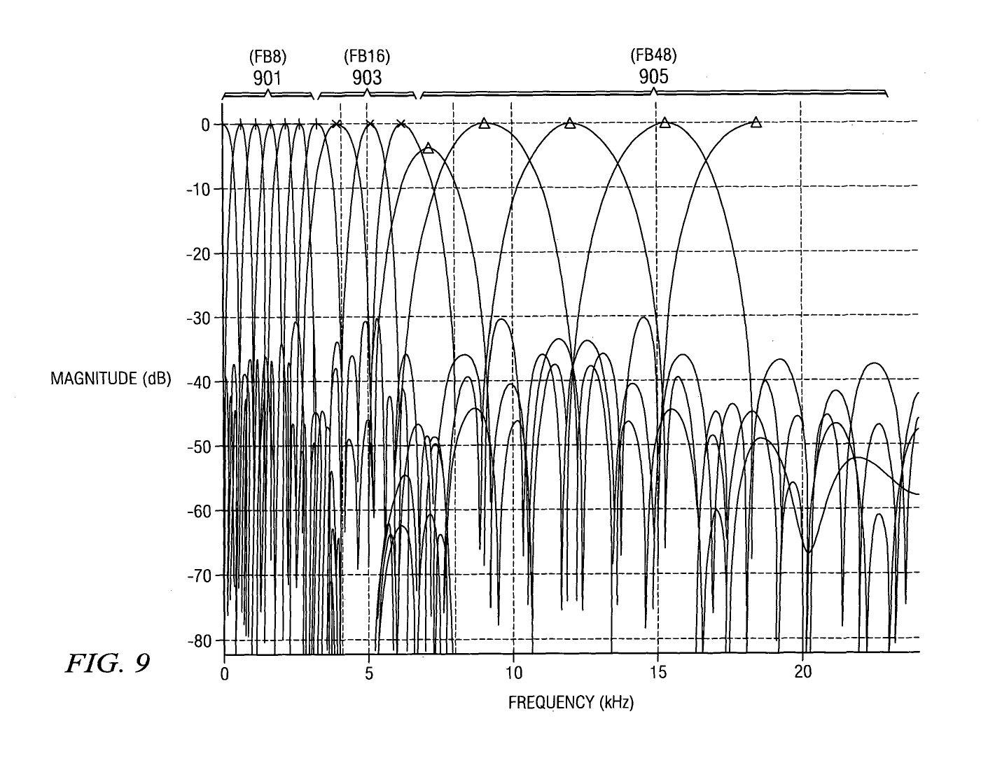

FIG. 8 shows schematically audio waveforms depicting the operation of the audio click suppressor according to embodiments of the invention; and

FIG. 9 shows schematically spectrograms depicting the sub-band filter banks responses according to embodiments of the invention.

### DESCRIPTION OF SOME EMBODIMENTS OF THE APPLICATION

The following describes apparatus and methods for the provision of improved audio capture devices and apparatus. In this regard reference is first made to FIG. 1 schematic block diagram of an exemplary electronic device 10 or apparatus, which incorporates an audio capture apparatus according to some embodiments of the application.

The electronic device 10 is in some embodiments a mobile terminal, mobile phone or user equipment for operation in a wireless communication system.

In other embodiments the electronic device 10 may be a multimedia device comprising a digital video camera.

The electronic device 10 comprises a microphone 11, which is linked via an analogue-to-digital converter 14 to a processor 21. The processor 21 is further linked via a digital-to-analogue converter 32 to loudspeakers 33. The processor 21 is further linked to a transceiver (TX/RX) 13, to a user interface (UI) 15 and to a memory 22.

The processor 21 may be configured to execute various program codes 23. The implemented program codes 23, in some embodiments, comprise audio capture digital processing or configuration code. The implemented program codes 23 in some embodiments further comprise additional code for further processing of the audio signal. The implemented program codes 23 may in some embodiments be stored for example in the memory 22 for retrieval by the processor 21 whenever needed. The memory 22 in some embodiments may further provide a section 24 for storing data, for example data that has been processed in accordance with the application.

The audio capture apparatus in some embodiments may be implemented in at least partially in hardware without the need of software or firmware.

The user interface 15 in some embodiments enables a user to input commands to the electronic device 10, for example via a keypad, and/or to obtain information from the electronic device 10, for example via a display.

It is to be understood again that the structure of the electronic device 10 could be supplemented and varied in many ways.

A user of the electronic device 10 may use the microphone 11 for recording an audio signal that is to be transmitted to some other electronic device or that is to be stored in the data section 24 of the memory 22. A corresponding application in some embodiments may be activated to this end by the user via the user interface 15. This application, which may in some embodiments be run by the processor 21, causes the processor 21 to execute the code stored in the memory 22.

The analogue-to-digital converter 14 may be configured, in some embodiments, to convert the input analogue audio signal into a digital audio signal and provides the digital audio signal to the processor 21.

The processor 21 may then process the digital audio signal in the same way as described with reference to FIGS. 2 and 3.

The resulting bit stream may in some embodiments be stored in the data section 24 of the memory 22, for instance for a later transmission or for a later presentation by the same electronic device 10 Alternatively, the coded data could be provided to the transceiver 13 for transmission to another electronic device.

In some embodiments the recorded audio signal may be processed in order to remove any audio clicks or pops.

The processed audio signal may in some embodiments also be stored instead of an immediate presentation via the loudspeakers 33 in the data section 24 of the memory 22, for instance for enabling a later presentation or a forwarding to another electronic device.

It would be appreciated that the schematic structures described in FIGS. 2, 3 and 5, and the method steps in FIGS. 4 and 7 represent only a part of the operation of a complete system comprising some embodiments of the application as shown implemented in the electronic device shown in FIG. 1.

FIG. 2 shows a schematic configuration view for audio capture apparatus including a microphone, analogue to digital converter, digital signal processor, digital audio controller and digital audio encoder. In other embodiments of the application the audio capture apparatus may comprise only the digital audio processor where a digital signal from an external source is input to the digital audio processor which has been preconfigured and further outputs an audio processed signal to an external encoder.

Where elements similar to those shown in FIG. 1 are described, the same reference numbers are used. The microphone 11 receives the audio waves and converts them into analogue electrical signals. The microphone 11 may be any suitable acoustic to electrical transducer. Examples of possible microphones may be capacitor microphones, electric microphones, dynamic microphones, carbon microphones, pizo-electric microphones, fibre optical microphones, liquid microphones, and micro-electrical-mechanical system (MEMS) microphones.

The capture of the analogue audio signal from the audio sound waves is shown with respect to FIG. 4 in step 301.

The electrical signal may be passed to the analogue to digital converter (ADC) 14.

The analogue to digital converter 14 may be any suitable analogue to digital converter for converting the analogue electrical signals from the microphone and outputting a digital signal. The analogue to digital converter may output a digital signal in any suitable form. Furthermore the analogue to digital converter 14 may be a linear or nonlinear analogue to digital converter dependent on the embodiment. For example the analogue to digital converter may in some embodiments be a logarithmic analogue to digital converter. The digital output may be passed to the digital audio processor 101.

The conversion of the analogue audio signal to a digital signal is shown in FIG. 4 by step 303.

The digital audio processor 101 may be configured to process the audio signal in order to detect and remove any audio clicks. A schematic representation of the structure of the digital audio processor is shown in further detail in FIG. 3.

The digital audio processor 101 may comprise a frequency band generator part 281 which receives the digital signal 280 from the analogue to digital converter 14 and, may in some embodiments and as shown in FIG. 3, divide the digital signal 280 into three frequency bands. The three frequency bands shown in FIG. 3 are a first (high frequency) band 291; a second (mid frequency) band 293; and a third (low frequency) band 295. In some embodiments the high frequency band 295 may be 8 kHz to 24 kHz (and therefore with a sampling frequency of 48 kHz), the mid frequency band 293 may be 4 kHz to 8 kHz (and requiring a sampling frequency of 16 kHz) and the low frequency band may be up to 4 kHz (and requiring a sampling frequency of 8 kHz).

It is to be appreciated in other groups of embodiments that the frequency band generator 281 may divide the digital signal 280 into a different number of bands.

The division of the signal into bands is shown in FIG. 4 by step 305.

The bands from the frequency band generator 281 may be connected to a time delay block 255, which can apply a time delay D to each band signal 291, 293 and 295.

The time delayed sub band signals may be connected to a sub-band filter bank 253. The sub-band filter bank 253 may, in some embodiments such as shown in FIG. 3, comprise a sub-band filter for each of the frequency bands. The high frequency band signals may be passed to a high frequency band sub-band filter 211, the mid frequency band signals may be passed to a mid frequency band sub-band filter 213, and the low frequency band signals may be passed to the low frequency band sub-band filter 215.

Each of the sub-band filters 211, 213, and 215 may be implemented and/or designed under the control of the digital audio controller 105. The sub-band filtering is carried out in order to obtain sufficient frequency resolution for audio click suppression. In some embodiments of the invention the digital audio controller 105 may configure cosine based modulated filter banks. This implementation may be chosen to simplify the synthesis implementation as these embodiments may recombine the processed sub-bands back to bands using summation.

FIG. 9 shows an example sub-band configuration frequency response output for a high frequency band sub-band filter for receiving 48 kHz sampled signals FB48 211, a mid frequency band sub-band filter for receiving 16 kHz sampled signals FB16 213 and a low frequency band sub-band filter for receiving 8 kHz sampled signals FB8 215. The frequency response from the low frequency band sub-band filter bank 215′ is shown by the crosses ‘+’ 901.

The frequency responses from the same filterbank design representing the ‘mid frequency band sub-band filter bank FB16 213’ is shown by the crosses ‘x’ 903

The frequency responses for the ‘high frequency band sub-band filter bank FB48 211’ is shown by the triangles ‘Δ’ 905.

The dividing of the bands into sub-bands is shown within FIG. 4 in step 309.

The sub band signals from the sub-band filter banks 253 are each passed to the audio suppressor 221.

It is to be appreciated that each sub band audio signal may have a bandwidth sufficiently narrow that it may be considered to represent the fine structure of the audio signal.

FIG. 9 depicts the three band signals 291, 293 and 295 being divided into a total of 15 individual sub band signals. However, it is to be understood that in other embodiments the sub band filter bank 253 may sub divide the band signals into a different arrangement of sub band signals.

Therefore, the digital audio processor 101 may further comprise a processing block arranged as an audio click suppressor 221 and configured to receive the sub-band audio signals, apply an audio click suppression algorithm to the sub-band signals and output the processed sub-band signals to the sub-band to band converter 257.

The processing block in other words the audio click suppressor processor 221 may be designed or configured by the digital audio controller 105 for suppression of audio clicks, pops and other sporadic audio distortions. The number of sub-bands processed by the processing block 221 may be determined by the digital audio controller 105 dependent on the audio application.

There is also depicted in FIG. 3 an audio click detector processor 217. The audio click detector processor 217 may be arranged to receive the audio signal from an analysis filter bank, and then process the audio signal in order to determine if an audio click or other sporadic audio distortion is present.

It is to be appreciated that the audio click detector processor 217 is depicted as receiving the mid frequency band audio signal 293 from the frequency band generator 281

However, in other embodiments the audio click detector processor 217 may be arranged to receive either the low frequency band audio signal 295 or the high frequency band audio signal 291. The audio click detector 217 in these embodiments may then perform audio click detection over these signals respectively.

Furthermore, in further embodiments the audio click detector processor 217 may be arranged to receive the full band audio signal, in other words the full input audio signal 280. These embodiments may then perform audio click detection over the full band of the signal.

A schematic representation of the structure of audio click detector 217 is shown in further detail in FIG. 5.

With reference to FIG. 5, the audio click detector 217 of the first group of embodiments may be arranged to receive the output of the mid frequency band audio signal 293.

It is to be appreciated however that an audio click or pop may resemble an impulse function in the time domain. When such a time domain function is represented in the frequency domain it can be considered to have reasonably flat spectrum. In other words, an audio click may be viewed as contributing energy across a wide spectrum of the audio signal.

It is to be further appreciated that as a result of the relatively flat spectrum the audio click may be detected in regions of the audio spectrum where there is little spectral energy contribution from the audio signal itself. In other words, since most speech and audio signals predominantly have their spectral energy concentrated amongst lower frequency regions, monitoring of middle and higher spectral frequency regions may have the advantage of contributing to the detection of audio clicks and pops.

In a first group of embodiments the higher frequencies within audio signal of the mid frequency band may be further emphasised by high pass filtering.

As explained above, the filtering operation may have the advantageous effect of increasing the detectability of any audio clicks.

The high pass filtering of the mid sub band filter bank audio signal can be depicted schematically in FIG. 5 as the pre-processing high pass filter 501.

In the first group of embodiments the pre-processing high pass filter 501 may have the frequency response depicted in FIG. 6, in which the higher frequencies over the mid-frequency band of 4 kHz to 8 kHz are emphasised.

With reference to FIG. 5, the audio click detector 503 is depicted as being arranged to receive the audio signals from the output of the pre-processing high pass filter 501.

With reference to the flow chart of FIG. 7, the operation of the audio click detector 503 is shown in more detail.

The audio click detector 503 may be arranged to detect a click in the audio signal by firstly determining the peak energy level in a current audio frame for a particular frequency band of the audio signal, and then secondly comparing the peak energy level of the current audio frame with the peak energy levels for neighboring audio frames before and after the current audio frame.

The audio click detector 503 may then compare the peak energy level determined for the current audio frame to the peak energy levels for the neighboring audio frames, and use the result of the comparison in order to determine if an audio click is present in the current audio frame.

The audio click detector 503 may determine that an audio click is present if the result of the above comparison step indicates that the peak energy value of the current frame exceeds the peak energy level of each of the neighboring audio frames by a pre-determined threshold value.

In a first group of embodiments the audio click detector 503 can determine the peak energy level in the current audio frame (for the mid-frequency band audio signal) by determining the energy of audio samples encompassed by a sliding window within the audio frame. Once the energy has been calculated for a first position of the window in the current audio frame, the window may then be advanced to a new consecutive position in the current audio frame. The calculation of the energy of the audio samples encompassed by the new position of the window can then be determined. This process may be repeated for each new position of the window until the entire length of the current audio frame has been traversed. The peak energy level may then be determined as the energy of the samples spanned by a particular window position in the current audio frame which gives a maximum value.

The calculation of the peak energy level for an audio frame may be expressed as

$$max ∈ ( n ) = \frac{1}{M} {\sum }_{i = 0}^{M - 1} {x}^{2} ( n - ( M - 1 ) + i )$$

$$0 < n < L - 1$$

where x(i) is an audio sample, M is the number of samples in the window, L is the length of the audio frame, and E (n) is the energy for the window of samples based around the sample position n.

In other words there is provided means for determining a peak energy level for an audio frame of a band limited audio signal.

In an application of a first group of embodiments the audio click may be produced by a camera shutter mechanism, where it has been observed that the audible click can have duration of approximately 1 ms.

In the above application of a first group of embodiments the audio frame can be of length 5 ms, in other words a frame length of L=80 samples for the audio signal of the mid frequency band. The window length can be chosen to be 1 ms (or M=16 samples at a sampling rate of 16 kHz) in order to coincide with the length of the camera shutter click. The position of the window within the audio frame can be updated on a sample by sample basis.

It is to be appreciated therefore in the above application the window can be traversed along the length of the audio frame at an update rate of one sample, and for each new sample position a value for the energy of the audio samples encompassed by the window can be calculated.

Experiments have shown that having a sample by sample approach to updating the window position produces an advantageous result when detecting audio clicks across the mid frequency sub band.

With reference to FIG. 7, the step of determining the peak energy level within the current audio frame is depicted as processing step 701.

It is to be understood that other examples of the first group of embodiments may be adapted for audio clicks with different characteristics and consequently parameters such as audio frame length, window size and the positional update rate of the window within audio frame may vary according to the characteristics of the audio click.

Once the audio click detector 503 has determined the peak energy level within the audio frame, the audio click detector 503 may then enter a multi-phase process in order to determine whether an audio click is present in the current audio frame.

The first phase of the process may compare the newly determined peak energy level for the current audio frame with the peak energy levels for other neighboring audio frames. In other words, the audio click detector 503 can compare the newly determined peak energy level for the current audio frame with the peak energy levels determined for consecutive audio frames before and after the current audio frame.

The determination of whether an audio click is present in a current audio frame may be dependent on whether the newly determined peak energy level exceeds the peak energy level values for each of the neighboring audio frames, and whether the amount by which the determined peak energy level exceeds is greater by a predetermined peak energy threshold value.

For example in the first group of embodiments in which a 5 ms frame size is deployed over the mid-frequency band, the current audio frame may be declared as having a potential audio click if the determined peak energy level of the current audio frame exceeds the peak energy level for each of the audio frames neighboring the current audio frame by the peak energy threshold value of 3 dB.

In the above example the peak energy level of the current audio frame may be compared against the peak energy level for each of the two consecutive audio frames before the current audio frame and each of the two consecutive audio frames after the current audio frame.

In other words there is provided means for determining that the peak energy level is a maximum peak energy level by determining that the peak energy level exceeds a peak energy level determined for at least one neighboring audio frame by a first predetermined energy threshold value.

The process of comparing the peak energy level in the current audio frame to the peak energy level of audio frames before and after the current audio frame is shown as processing step 703 in FIG. 7.

From the flow chart in FIG. 7 it can be seen that the decision whether the peak energy level determined for the current audio frame is a potential audio click is taken by decision step 705.

With reference to FIG. 7, the decision step 705 has two outputs. The first output branch 705a indicates that the determined peak energy level is not a potential audio click by virtue of the above comparison step not reaching the predetermined threshold value. In this first decision step the audio click detector 503 determines that the current audio frame does not contain an audio click.

The step in which the audio click detection process terminates on the decision that the determined peak energy for the current audio frame is not an audio click is depicted in FIG. 7 as processing step 708.

With reference to FIG. 7, it can be seen that the second output branch 705b is taken as a result of the peak energy level exceeding the predetermined threshold value. In this second decision instance the audio click detector 503 has determined that the current audio frame may contain a potential audio click. As a consequence of this decision the audio click detector 503 may enter into a second phase of the audio click detection process.

In some groups of embodiments the second phase of the click detection process may incorporate a processing step whereby the peak energy level is compared against an estimated peak level. This processing step may be known in groups of embodiments as the estimated peak level condition.

The audio click detector 503 may then use the outcome of the above estimated peak level condition processing step in order to further assist in the determination whether the audio samples associated with the peak energy level is an audio click.

The audio click detector 503 may use the outcome of the comparison step to determine if the peak energy level is not an audio click. For example the audio click detector 503 may determine that the peak energy level is outside the bounds of a pre-determined threshold value below with relation to the estimated peak level. In this instance, the audio click detector 503 may determine that the audio samples associated with the peak energy level can be categorized as a non-audio click.

Alternatively, in the instance that the audio click detector 503 determines that the peak energy level is within the bounds of the pre-determined threshold value, the audio frame may be categorized as containing a potential audio click. As a consequence of this decision the audio click detector 503 may enter into a third phase of the audio click detection process.

For example in the first group of embodiments the audio click detector 503 may categorize the peak energy level as being a potential audio click if the value of the peak energy level is within 9 dB from the estimated peak level. If the audio click detector 503 determines that the peak energy level lies outside the threshold interval then the current audio frame may be determined as not containing an audio click.

In some embodiments the estimated peak level may be generated by weighting past estimated peak level values with current Peak energy levels

In a first group of embodiments the estimated peak level may be generated on the basis of the following expression for an average exponential estimator

Peaklevelₛₑₜ=((1−γ)*PeaklevelPastₑₛₜ)+(γ*Peaklevel),

where Peaklevelₑₛₜ is the estimated peak level for a current audio frame.

The estimated peak level Peaklevelₑₛₜ can be updated for the next audio frame according to the above equation, where the update can be dependent on the stored (or previous) estimated peak level PeaklevelPastₑₛₜ and the peak energy level for the current audio frame Peaklevel. It can be seen from the above equation that the distribution of PeaklevelPastₑₛₜ and Peaklevel making up the new estimated peak level Peaklevelₑₛₜ can be affected by the value of the leakage factor γ.

The value of γ may be determined experimentally to produce an advantageous result.

For instance, in the example of the first group of embodiments values for γ of 0.0078125, 0.0625 and 0.0019531 have been found to provide an advantageous result.

Furthermore, in some embodiments the peak level estimate Peaklevelₑₛₜ may only be updated on the basis that the value of the current audio frame peak energy level Peaklevel is of a certain threshold value, a peak level estimate threshold value.

For instance, in the first group of embodiments the estimated peak level Peaklevelₑₛₜ may only be updated for a next audio frame depending on whether the peak energy level Peaklevel is within a predetermined range from an initial peak energy level, and whether the peak energy level Peaklevel is above the signal level for the current audio frame by a threshold amount.

In an example of the first group of embodiments the estimated peak level Peaklevelₑₛₜ may only be updated for a next audio frame if the peak energy level for the current audio frame Peaklevel is within a range of 3 dB above or below an initial peak level, and if the peak energy level for the current audio frame Peaklevel is at least 9 dB above the signal level for the current audio frame.

Therefore it is to be appreciated in some embodiments the peak level estimate Peaklevelₑₛₜ may not be updated on a frame by frame basis.

In a first group of embodiments the initial peak energy level used for the above expression of estimated peak energy level can be made dependent on an assumed value for the sensitivity of the microphone 11.

The step of comparing the peak energy level for the current audio frame to the estimated peak energy level is shown as processing step 713 in FIG. 7.

Furthermore, FIG. 7 also shows the decision step taken as a result of the comparison 713 in which the audio samples associated with the peak energy level are determined to be either a potential audio click or a not an audio click.

Branch 707a in FIG. 7 represents the audio click detector 503 taking the decision that the audio samples associated with the peak energy level do not constitute an audio click. Branch 707a terminates at the processing step 708 in which the audio detector 503 declares that there is no audio click in the audio frame.

Branch 707b in FIG. 7 represents the audio click detector 503 taking the decision that the audio samples associated with the peak energy level may constitute a potential audio click. As a consequence of this decision the audio click detector 503 may enter into a third phase of the audio click detection process.

Upon entry into the third phase of the audio click detection process the audio click detector 503 may utilise a representation of the signal level.

The signal level may be determined to by taking the peak energy levels calculated for the current audio frame, the preceding audio frames and the proceeding audio frames, and then selecting a minimum peak energy level. In other words the signal level may be determined as the minimum of the peak energy levels calculated for a series of consecutive audio frames centred about the current audio frame.

In a first group of embodiments the signal level may be determined as the minimum of the peak energy levels calculated for the two audio frames preceding the current audio frame, and the two audio frames preceding the current audio frame. In other words the signal level may be given by the minimum of the peak energy levels as determined for processing step 703.

In the first group of embodiments the click detector 503 may determine the signal level in an audio frame of the mid-frequency sub band.

Furthermore, in the first group of embodiments the processing step of determining the signal level may be performed at the same time as when the peak energy level is determined for the current audio frame.

The step of determining the signal level for the current audio frame is depicted as the processing step 709 in FIG. 7.

The third phase of the click detection process may then compare the peak level estimate Peaklevelₑₛₜ to the signal level in order to determine if the peak level estimate exceeds the signal level by an amount which exceeds a signal level threshold value.

The audio click detector 503 may then use the outcome of the above signal level condition in order to further assist in determining whether the audio samples associated with the peak energy level for the current audio frame is an audio click.

For example, the audio click detector 503 may determine that the peak level estimate Peaklevelₑₛₜ exceeds the signal level by the signal level threshold amount. In this instance the audio click detector 503 may use the result as an indication that the peak energy level may be associated with an audio click.

Alternatively, the audio click detector 503 may determine that the peak level estimate is below the signal level threshold amount. In this instance the audio click detector 503 may determine that the audio samples associated with the peak energy level is not an audio click.

In some groups of embodiments this comparison step may be known as the signal level condition.

It is to be understood that some groups of embodiments may apply audio click detection to multi-channel audio signals. In other words the processes of audio click detection and audio click suppression may be applied to each channel of a multi-channel audio signal in turn. For example, a particular operating scenario may comprise a stereo system whereby audio click detection and suppression maybe applied to each channel individually.

In a first group of embodiments the signal level condition comparison step may be applied to each individual channel of a stereo system.

If one of the channels determines that the peak level estimate differs from the signal level by the pre-determined threshold amount, then the audio click detector 503 may determine that there may be an audio click present. It is to be appreciated that applying audio click detection over two channels of a stereo system may have the advantage of reducing the number of false click detections in a channel.

For example, for a first channel of the at least two channels it may be determined that the peak estimated level Peaklevelₑₛₜ differs from the signal level by less than the pre-determined signal level threshold. In other words the peak energy associated with a potential audio click is not conclusively discernible from the signal level. In this instance if it is detected in a second channel of the least two channels that the peak estimated level Peaklevelₑₛₜ differs from the signal level by above the pre-determined signal level threshold. Then it may be determined by the audio click detector 503 that there may be an audio click present.

An operating scenario for the above example may occur when the click produced by a camera is closer to the microphone associated with the first channel than the microphone associated with the second channel.

Obviously should both channels have a peak estimated level which differs from the signal level by the pre-determined signal level threshold then the audio click detector 503 may also determine that there may be an audio click present.

In the example of the first group of embodiments a pre-determined signal level threshold of 9 dB was found to assist in the determination of whether the peak energy level can be classified as an audio click. The signal level threshold value of 9 dB was determined experimentally to produce an advantageous result.

The step of comparing the signal level of the current audio frame to the previously calculated estimated peak energy level is shown as processing step 711 in FIG. 7.

Furthermore, FIG. 7 also shows the decision step 715 taken as a result of the comparison 711. In other words a decision is taken in which the audio samples associated with the peak energy level are determined to be either a potential audio click or a not an audio click.

Branch 715a in FIG. 7 represents the decision taken by the audio click detector 503 that the audio samples associated with the peak energy level do not constitute an audio click. Branch 715a terminates at the processing step 708 in which the audio click detector 503 declares that there is no audio click in the audio frame.

Branch 715b in FIG. 7 represents the decision taken by the audio click detector 503 that the audio samples associated with the peak energy level may constitute a potential audio click. As a consequence of this decision the audio click detector 503 may enter into a fourth phase of the audio click detection process.

Upon entry into the fourth phase of the audio click detection process the audio click detector 503 may utilise a representation of the minimum peak energy level for the current audio frame.

In some groups of embodiments the minimum energy level may be determined by calculating the energy of audio samples encompassed by a sliding window within the current audio frame. In other words, the same process as used above for determining the peak energy level. However, rather than determining the position of the window in the audio frame which give a maximum value, the minimum energy level may be determined as the energy of the samples spanned by a particular window position which give a minimum value.

Therefore, in the first group of embodiments the audio click detector 503 can determine a minimum energy level over the length of the audio frame by determining the energy of audio samples encompassed by a sliding window within the audio frame. Once the energy has been calculated for a first position of the window in the audio frame, the window may then be moved to a new consecutive position in the audio frame. The calculation of the energy of the audio samples encompassed by the new position of the window can then be determined. This process may be repeated for each new position of the window until the entire length of the audio frame has been traversed.

The step of determining the minimum energy level is shown in FIG. 7 as the processing step 716.

However, in the first group of embodiments in which the current audio frame can be of 5 ms length the window length is selected to be 1 ms the signal level may be determined along with the calculations for the peak energy level rather than as a separate processing step.

The minimum energy level for the current audio frame may be used by the audio click detector 503 to reduce the number of false detections of audio clicks by comparing the determined minimum energy level against the signal level for the current audio frame. The comparison of the signal level to the minimum energy level may allow for the detection of any sudden rises in the signal level.

It is to be appreciated that the comparison of the minimum energy level against the signal level may be used to distinguish between a rising signal level which may be a characteristic of the signal and an audio click. For example the current audio frame may comprise music audio samples which may exhibit rapid fluctuations in signal level.

In some groups of embodiments the minimum energy level may be compared to the signal level and checked if the peak energy level exceeds the minimum energy level by a threshold value. If it is determined that that the signal level exceeds the minimum energy level by a threshold amount then this may be indicative of a sudden rise in the signal level which is not attributed to an audio click

Conversely, if it is determined that the minimum energy level for the current frame is near or above the signal level by a threshold amount this may be indicative that the peak energy level of the current frame is an audio click. Consequently, in this case the audio click detector 503 may determine that the audio samples of the current frame do comprise an audio click.

The step of comparing the signal level to the minimum energy level may be used to assist in the distinction between a rapid fluctuation in the audio signal and an audio click.

The step of comparing the minimum energy level of the current audio frame to the signal level is shown as processing step 717 in FIG. 7.

Furthermore, FIG. 7 also shows the decision step taken as a result of the comparison 718. In other words a decision is taken in which the audio samples associated with the peak energy level are determined to be an audio click.

Branch 718a in FIG. 7 represents the decision taken by the audio click detector 503 that the audio samples associated with the peak energy level do not constitute an audio click. Branch 718a terminates at the processing step 708 in which the audio click detector 503 declares that there is no audio click in the audio frame.

Branch 718b in FIG. 7 represents the decision taken by the audio click detector 503 that the audio samples associated with the peak energy level may constitute an audio click. As a consequence of this decision the audio click detector 503 may determine that the audio samples associated with the peak energy level is an audio click.

Therefore it is to be appreciated that the output of the decision step 718 may indicate whether an audio click is present in the current audio frame.

The step of determining that the audio samples associated with the peak energy level is an audio click is shown in FIG. 7 as processing step 719.

In other words there is provided means for classifying a region of audio samples associated with the maximum peak energy level as an audio click.

It is to be appreciated that other groups of embodiments may deploy an audio click detection process comprising a sub set of the above process steps.

For example, some groups of embodiments the audio click detector 503 may deploy the processing steps involved in the estimated peak level condition and the signal level condition in determining whether an audio click is present in the current audio frame.

With reference to FIG. 7 this particular group of embodiments may deploy an audio click detection process having the processing steps 701 to 715. In this group of embodiments the output of the decision step 715 would result on a decision whether the audio samples associated with the peak energy level is an audio click.

From the above description it is to be appreciated therefore, that the audio click detector 217 may then incur a delay equal to the number of audio frames over which the comparison process is performed before the current audio frame. Consequently, there is shown in FIG. 3 a delay block 255 which represents the time delay applied to each band signal output of the frequency generator 281. The time delay may be applied in order to firstly take into account the delay introduced by the audio click detector processor 217, and secondly to ensure that all band signals presented to the sub band filter bank 253 are time aligned.

The output from the audio click detector 217 can be a flag denoting whether the current audio frame comprises an audio click.

With reference to FIG. 3, the output of the audio click detector 217 may be connected to the audio click suppressor 221 via the signalling line 218. The signalling line 218 can then convey to the audio click suppressor 221 whether audio click suppression is required for the current audio frame.

Additionally, the audio click suppressor 221 can be arranged to receive the sub band audio signals from the high frequency sub bank filter bank FB48 (211), the mid frequency sub band filter bank FB16 (213), and the low frequency sub band filter bank FB8 (215). In other words the sub band audio signals over which audio click suppression is to be applied.

The audio click suppressor 221 can be arranged to apply audio click suppression across all the audio sub band signals. On other words the audio click suppression may be applied to each of the audio sub band signals emanating from the filter banks FB8, FB16 and FB48. This may be viewed as achieving audio click suppression across the full band of the audio signal by applying audio click suppression to each individual audio sub band signal in turn.

The audio click suppressor 221 can suppress the detected audio click in the current audio frame by forcing the peak energy level of the section of the audio signal containing the audio click to be equivalent to the signal level of a section of audio signal preceding the section of audio signal containing the click.

In some embodiments the audio click may be suppressed by applying a sub band specific suppressor gain to each of the sub band audio signals in turn. In other words, the audio click suppressor can determine a suppressor gain for a particular sub band signal, and then apply the suppressor gain to the particular sub band signal. This process can be repeated on a per sub band basis for each of the sub band signals passed to the audio click suppressor 221.

In some embodiments the suppressor gain for a particular sub band signal of a current audio frame n can be determined as the ratio of a long term tracked (or smoothed) amplitude of the samples in the current audio frame n to the sample wise signal amplitude of the samples within the current audio frame n.

The above ratio may be expressed in some embodiments as

$$g ( n , m ) = \frac{β * long\_amp ( n - 1 )}{samp\_amp ( m )} ,$$

where g(n, m) represents the suppressor gain for the current audio frame n of a particular sub band signal, and for a particular sample m within the current audio frame. In other words, the suppressor gain may vary on a sample by sample basis across the length of the current audio frame n. β is a constant which may be determined experimentally to produce an advantageous result.

In other words there may be provided a sample wise suppressor gain function for at least one sample of the audio frame is dependent at least in part upon the ratio of a determined smoothed signal amplitude value for the audio frame and a sample wise signal amplitude value for the at least one sample of the audio frame.

Alternatively in some embodiments the sample wise suppressor gain function for at least one sample of the audio frame may be viewed as being dependent at least in part upon the ratio of a determined long term tracked amplitude value for the audio frame and a sample wise signal amplitude value for the at least one sample of the audio frame.

For example, in the first group of embodiments a value for β of two was found experimentally to provide an advantageous result.

The combination of β with the long term tracked (or smoothed) term signal amplitude for the current audio frame n may be considered as an envelope function for the long term absolute sample values m for the current audio frame.

For a current audio frame, n, long term tracked (or smoothed) absolute sample values long_amp(n) may be provided by using an average exponential estimator of the form

long_amp(n)=α*long_amp(n−1)+(1−α)*frame_amp(n).

Where frame_amp(n) is the mean of the absolute sample values for the current audio frame n

$$frame\_amp ( n ) = \frac{1}{N} {\sum }_{i = 0}^{N - 1} \vert x ( n - i ) \vert$$

Where N is the number of samples in the current audio frame, and |x(n)| is an absolute sample value for the current audio frame n.

The term α may be considered as a leakage factor which controls how quickly the long term tracked (or smoothed) amplitude long_amp(n) adjusts to the current frame's absolute sample values.

In the example of the first group of embodiments it was found that a leakage factor of 0.9 and 0.99 was found to be suitable.

The above leakage factor was obtained through experimental observations and was selected in order to give an advantageous result.

It is to be appreciated in the above equation for the suppressor gain g(n,m) that the long term tracked (or smoothed) amplitude for the previous frame is used for in the calculation.

In other words the determined long termed tracked signal amplitude value (or smoothed signal amplitude value) for the audio frame is updated on an audio frame by audio frame basis and is dependent on the combination of a past long termed tracked signal amplitude value (or past smoothed signal amplitude value) and a mean absolute amplitude value for the audio frame.

The sample wise signal amplitude in the denominator of the above expression for suppressor gain g(n, m) may be viewed as an envelope function which tracks on a short term basis the shape of the signal amplitude within the current audio frame.

In embodiments the samp_amp(m) for a sample m may take the form of

max(|x(m−l)|,|x(m−l+1)|, . . . , |x(m)|, . . . , |x(m+l−1)|,|x(m+l)

In other words, the sample wise signal amplitude at a sample instance m within the current audio frame n can be the maximum absolute sample value of a group of consecutive sample values centred about the sample at time instance m.

In the above expression for samp_amp(m) the maximum absolute sample value will be drawn from the set of samples comprising the sample at time instance m, the l samples after the sample at time instance m, and the l samples before the sample at time instance m.

The advantage of the samp_amp(m) function is to provide an envelope function which tracks the magnitude of the samples within the audio frame over a short term basis.

It is to be appreciated in embodiments that the samp_amp(m) function can be calculated for each m sample value for the current audio frame.

In other words there may be provided a sample wise signal amplitude value for the at least one sample of the audio frame which is dependent on the maximum sample value of a plurality of samples encompassing the at least one sample of the audio frame.

With reference to FIG. 8, there is shown a schematic representation of how the suppressor gain function would be characterised for a sub band signal of a current audio frame n in which an audio click has been detected.

With reference to waveform 8.1 in FIG. 8, there is shown a schematic representation of a sub band audio signal frame containing a detected audio click.

The waveform 8.2 depicts the absolute value for the schematic representation of the sub band audio signal frame of 8.1.

The waveform 8.3 depicts the long term tracked (or smoothed) average value for the schematic representation of the sub band audio signal frame of 8.1. In other words the numerator of the suppressor gain g(n, m).

The waveform 8.4 depicts the sample wise signal amplitude samp_amp(m) for the schematic representation of the sub band audio signal frame of 8.1. It can be seen that the function samp_amp(m) may track the amplitude profile of the waveform 8.1, and additionally smooth out the sample to sample fluctuations of the waveform.

As described above a suppressor gain g(n, m) for a sample value m may be given by the ratio of the long term average for the frame n to the sample wise signal amplitude for the sample m. The advantage of determining the suppressor gain g(n, m) to be of the above form is that the suppressor gain factor will have a gain profile which results in an attenuation effect when there is a detected audio peak.

With reference to the schematic waveforms of FIG. 8, waveform 8.5 depicts the suppressor gain profile for the detected audio click of 8.1. From waveform 8.5 it can be seen that the gain profile is low during the region of the audio click. In other words the audio signal is being attenuated in the region of the click.

In some groups of embodiments the suppressor gain g(n,m) is not updated for every sample m within the audio frame n.

For example, in the groups of embodiments arranged to detect and suppress audio clicks from a camera shutter mechanism it has been found from experimental observations that a shutter click may have approximately a 1 ms duration. These groups of embodiments may then adopt a suppressor gain update rate of four times for every millisecond of audio frame length. In other words if the audio frame is taken from the mid-frequency filter bank (FB16), then the suppressor gain will be updated every 4 samples.

As stated before, in some groups of embodiments audio click suppression may be applied by the audio click suppressor 221 to each of the sub band signals emanating from the low, mid and high frequency sub band filter banks (FB8, FB16 and FB48).

However, other groups of embodiments may apply audio click suppression to a sub set of the sub band signals emanating from the from the low, mid and high frequency sub band filter banks (FB8, FB16 and FB48). For instance, further groups of embodiments may apply audio click suppression across sub band signals emanating from the low and mid sub band filter banks.

In other words there may be provided means for suppressing audio samples of a region of audio samples classified as an audio click by multiplying at least one audio sample of the audio frame with a sample wise suppressor gain function.

It is to be understood that embodiments may be applied to multi-channel audio signals. In other words the processes of audio click detection and audio click suppression may be applied to each channel of a multi-channel audio signal in turn.

The application of the audio click suppression to at least one sub band signal is shown in FIG. 4 by step 311.

The audio click suppressor 221 outputs the processed signal to a sub-band to band converter 257 and a synthesis filter bank 259.

The output of the audio click suppressor 221 may be configured to be connected to the sub-band to band converter 257 and may in embodiments receive from the audio click suppressor 221 the processed sub-band signals and output to the synthesis filter bank 259 combined processed frequency band signals.

The sub-band to band converter 257 may comprise three summation devices, each device configured to receive the processed sub-band signals for one of the frequency bands and further configured to sum the received sub-band signals to generate the processed frequency band signals.

In other words the sub-band to band converter 257 may comprise a high frequency band summation device configured to sum the processed audio signals associated with the sub-bands for the 48 kHz high frequency band and combine the signals to output a high frequency band processed signal to the synthesis filter bank 259. Furthermore the sub-band to band converter 257 in some embodiments may comprise a mid frequency band summation device configured to sum the processed audio signals associated with the sub-bands for the 16 kHz mid frequency band and combine the signals to output a mid frequency band processed signal to the synthesis filter bank 259. In these embodiments the sub-band to band converter 257 may further comprise a low frequency band summation device configured to sum the processed audio signals associated with the sub-bands for the 8 kHz low frequency band and combine the signals to output a low frequency band processed signal to the synthesis filter bank 259.

The combining of the processed sub-bands to output processed frequency band signals is shown in FIG. 4 by step 313.

The synthesis filter bank 259 may therefore in some embodiments receive the processed digital audio signal divided into frequency bands and filter and combine the bands to generate a single processed digital audio signal.

The combined single processed digital audio signal is shown as signal 297 in FIG. 3.

The operation of combining the processed band is shown in FIG. 4 by step 317.

The digital audio encoder 103 may further encode the combined processed digital 297 audio signal according to any suitable encoding process. For example the digital audio encoder 103 may apply any suitable lossless or lossy encoding process such as any of the International Telecommunications Union Technical board (ITU-T) G.722 or G729 coding families. In some embodiments the digital audio encoder 103 is optional and may not be implemented.

The operation of further encoding of the audio signal is shown in FIG. 4 by step 319.

Although the above has been described with regards to mono signals, stereo signals and polyphonic signals may also be applied to various embodiments.

Thus in some embodiments of the application there may be a method comprising determining a peak energy level for an audio frame of a band limited audio signal; determining that the peak energy level is a maximum peak energy level by determining that the peak energy level exceeds a peak energy level determined for at least one neighboring audio frame by a first predetermined energy threshold value; classifying a region of audio samples associated with the maximum peak energy level as an audio click; and suppressing audio samples of the region of audio samples classified as an audio click by multiplying at least one audio sample of the audio frame with a sample wise suppressor gain function.

In some other embodiments there may be apparatus comprising at least one processor and at least one memory including computer program code the at least one memory and the computer program code configured to, with the at least one processor, cause the apparatus at least to perform the operations described above.

Furthermore in some embodiments apparatus may have means for determining a peak energy level for an audio frame of a band limited audio signal; means for determining that the peak energy level is a maximum peak energy level by determining that the peak energy level exceeds a peak energy level determined for at least one neighboring audio frame by a first predetermined energy threshold value; means for classifying a region of audio samples associated with the maximum peak energy level as an audio click; and means for suppressing audio samples of the region of audio samples classified as an audio click by multiplying at least one audio sample of the audio frame with a sample wise suppressor gain function.

Although the above examples describe embodiments of the invention operating an within an electronic device 10 or apparatus, it would be appreciated that the invention as described below may be implemented as part of any audio processing stage within a chain of audio processing stages.

Furthermore user equipment, universal serial bus (USB) sticks, and modem data cards may comprise audio capture apparatus such as the apparatus described in embodiments above.

It shall be appreciated that the term user equipment is intended to cover any suitable type of wireless user equipment, such as mobile telephones, portable data processing devices or portable web browsers.

Furthermore elements of a public land mobile network (PLMN) may also comprise audio capture and processing apparatus as described above.

In general, the various embodiments described above may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

The embodiments of the application may be implemented by computer software executable by a data processor, such as in the processor entity, or by hardware, or by a combination of software and hardware. Further in this regard it should be noted that any blocks of the logic flow as in the Figures may represent program steps, or interconnected logic circuits, blocks and functions, or a combination of program steps and logic circuits, blocks and functions. The software may be stored on such physical media as memory chips, or memory blocks implemented within the processor, magnetic media such as hard disk or floppy disks, and optical media such as for example digital versatile disc (DVD), compact discs (CD) and the data variants thereof both.

The memory may be of any type suitable to the local technical environment and may be implemented using any suitable data storage technology, such as semiconductor-based memory devices, magnetic memory devices and systems, optical memory devices and systems, fixed memory and removable memory. The data processors may be of any type suitable to the local technical environment, and may include one or more of general purpose computers, special purpose computers, microprocessors, digital signal processors (DSPs), application specific integrated circuits (ASIC), gate level circuits and processors based on multi-core processor architecture, as non-limiting examples.

Embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

As used in this application, the term circuitry may refer to all of the following: (a) hardware-only circuit implementations (such as implementations in only analogue and/or digital circuitry) and (b) to combinations of circuits and software (and/or firmware), such as and where applicable: (i) to a combination of processor(s) or (ii) to portions of processor(s)/software (including digital signal processor(s)), software, and memory(ies) that work together to cause an apparatus, such as a mobile phone or server, to perform various functions) and (c) to circuits, such as a microprocessor(s) or a portion of a microprocessor(s), that require software or firmware for operation, even if the software or firmware is not physically present.

This definition of circuitry applies to all uses of this term in this application, including in any claims. As a further example, as used in this application, the term circuitry would also cover an implementation of merely a processor (or multiple processors) or portion of a processor and its (or their) accompanying software and/or firmware. The term circuitry would also cover, for example and if applicable to the particular claim element, a baseband integrated circuit or applications processor integrated circuit for a mobile phone or a similar integrated circuit in server, a cellular network device, or other network device.

The term processor and memory may comprise but are not limited to in this application: (1) one or more microprocessors, (2) one or more processor(s) with accompanying digital signal processor(s), (3) one or more processor(s) without accompanying digital signal processor(s), (3) one or more special-purpose computer chips, (4) one or more field-programmable gate arrays (FPGAS), (5) one or more controllers, (6) one or more application-specific integrated circuits (ASICS), or detector(s), processor(s) (including dual-core and multiple-core processors), digital signal processor(s), controller(s), receiver, transmitter, encoder, decoder, memory (and memories), software, firmware, RAM, ROM, display, user interface, display circuitry, user interface circuitry, user interface software, display software, circuit(s), antenna, antenna circuitry, and circuitry.

1-36. (canceled)

37. A method comprising:
determining a peak energy level for an audio frame of a band limited audio signal;
determining that the peak energy level is a maximum peak energy level by determining that the peak energy level exceeds a peak energy level determined for at least one neighboring audio frame by a first predetermined energy threshold value;
classifying a region of audio samples associated with the maximum peak energy level as an audio click; and
suppressing audio samples of the region of audio samples classified as an audio click by multiplying at least one audio sample of the audio frame with a sample wise suppressor gain function.

38. The method as claimed in claim 37, wherein the sample wise suppressor gain function for the at least one sample of the audio frame is dependent at least in part upon a ratio of a determined long term tracked signal amplitude value for the audio frame and a sample wise signal amplitude value for the at least one sample of the audio frame.

39. The method as claimed in claim 38, wherein the sample wise signal amplitude value for the at least one sample of the audio frame is dependent on the maximum sample value of a plurality of samples encompassing the at least one sample of the audio frame.

40. The method as claimed in claim 38, wherein the determined long term tracked signal amplitude value for the audio frame is updated on an audio frame by audio frame basis and is dependent on the combination of a past long term tracked signal amplitude value and a mean absolute amplitude value for the audio frame.

41. The method as claimed in claim 37, wherein the determining that the peak energy is a maximum peak energy level further comprises:
determining that the peak energy level of the audio frame is within a second predetermined energy threshold value of an estimated maximum peak energy level for the audio frame,

42. The method as claimed in claim 41 wherein the estimated maximum peak energy level is determined by:
weighting a past estimated maximum peak energy level with a first weighting factor;
weighting a maximum peak energy level for a previous audio frame with a second weighting factor; and
combining the weighted past estimated maximum peak energy level with the weighted maximum peak energy level for the previous audio frame, wherein the first and second weighting factors control the rate of adaptation of the estimated maximum peak energy level to the peak energy level of the audio frame.

43. The method as claimed in claim 41, wherein the determining that the peak energy level is a maximum peak energy level further comprises:
determining a signal energy level for the audio frame, wherein the signal energy level is a minimum of the at least one peak energy level determined for the audio frame and the at least one neighboring audio frame;
comparing the signal energy level for the audio frame to the estimated maximum peak energy level; and
determining that the estimated maximum peak energy level exceeds the signal level by a third predetermined energy threshold value.

44. The method as claimed in claim 37, wherein the determining the peak energy level for the audio frame of the band limited audio signal comprises:
determining an energy value for a plurality of consecutive audio samples encompassed within the audio frame;
determining a further energy value of a further plurality of consecutive audio samples within the audio frame, wherein the plurality of consecutive audio samples and the further plurality of consecutive audio samples overlap within the audio frame; and
selecting the peak energy level for the audio frame to be the maximum of the energy value and the further energy value.

45. The method as claimed in claim 37, wherein the determining that the peak energy level is a maximum peak energy level further comprises:
determining a minimum signal level for the audio frame; and
determining that the peak energy level for the audio frame exceeds the minimum signal level for the audio frame by an amount which is below a fourth predetermined energy threshold value.

46. The method as claimed in claim 45, wherein determining the minimum signal level for the audio frame comprises:
determining an energy value for a plurality of consecutive audio samples encompassed within the audio frame;
determining a further energy value of a further plurality of consecutive audio samples within the audio frame, wherein the plurality of consecutive audio samples and the further plurality of consecutive audio samples overlap within the audio frame; and
selecting the minimum signal level for the audio frame to be the minimum of the energy value and the further energy value.

47. The method as claimed in claim 37, wherein the sample wise suppressor gain function applied to the at least one audio sample is applied to at least one sample of a sub band audio signal of the band limited audio signal.

48. An apparatus comprising at least one processor and at least one memory including computer code for one or more programs, the at least one memory and the computer code configured with the at least one processor to cause the apparatus to:
determine a peak energy level for an audio frame of a band limited audio signal;
determine that the peak energy level is a maximum peak energy level by determining that the peak energy level exceeds a peak energy level determined for at least one neighboring audio frame by a first predetermined energy threshold value;
classify a region of audio samples associated with the maximum peak energy level as an audio click; and
suppress audio samples of the region of audio samples classified as an audio click by multiplying at least one audio sample of the audio frame with a sample wise suppressor gain function.

49. The apparatus as claimed in claim 48, wherein the sample wise suppressor gain function for the at least one sample of the audio frame is dependent at least in part upon a ratio of a determined long term tracked signal amplitude value for the audio frame and a sample wise signal amplitude value for the at least one sample of the audio frame.

50. The apparatus as claimed in claim 49, wherein the sample wise signal amplitude value for the at least one sample of the audio frame is dependent on the maximum sample value of a plurality of samples encompassing the at least one sample of the audio frame.

51. The apparatus as claimed in claim 49, wherein the determined long term tracked signal amplitude value for the audio frame is updated on an audio frame by audio frame basis and is dependent on the combination of a past long term tracked signal amplitude value and a mean absolute amplitude value for the audio frame.

52. The apparatus as claimed in claim 48, wherein the at least one memory and the computer code configured with the at least one processor to cause the apparatus to determine that the peak energy is a maximum peak energy level is further configured to cause the apparatus to:
determine that the peak energy level of the audio frame is within a second predetermined energy threshold value of an estimated maximum peak energy level for the audio frame,

53. The apparatus as claimed in claim 52 wherein the estimated maximum peak energy level is determined by causing the apparatus to:
weight a past estimated maximum peak energy level with a first weighting factor;
weight a maximum peak energy level for a previous audio frame with a second weighting factor; and
combine the weighted past estimated maximum peak energy level with the weighted maximum peak energy level for the previous audio frame, wherein the first and second weighting factors control the rate of adaptation of the estimated maximum peak energy level to the peak energy level of the audio frame.

54. The apparatus as claimed in claim 52, wherein the at least one memory and the computer code configured with the at least one processor to cause the apparatus to the determine that the peak energy level is a maximum peak energy level further comprises level is further configured to cause the apparatus to:
determine a signal energy level for the audio frame, wherein the signal energy level is a minimum of the at least one peak energy level determined for the audio frame and the at least one neighboring audio frame;
compare the signal energy level for the audio frame to the estimated maximum peak energy level; and
determine that the estimated maximum peak energy level exceeds the signal level by a third predetermined energy threshold value.

55. The apparatus as claimed in claim 48, wherein the at least one memory and the computer code configured with the at least one processor to cause the apparatus to determine that the peak energy level for the audio frame of the band limited audio signal is further configured to cause the apparatus to:
determine an energy value for a plurality of consecutive audio samples encompassed within the audio frame;
determine a further energy value of a further plurality of consecutive audio samples within the audio frame, wherein the plurality of consecutive audio samples and the further plurality of consecutive audio samples overlap within the audio frame; and
select the peak energy level for the audio frame to be the maximum of the energy value and the further energy value.

56. The apparatus as claimed in claim 48, wherein the at least one memory and the computer code configured with the at least one processor to cause the apparatus to determine that the peak energy level is a maximum peak energy level is further configured to cause the apparatus to:
determine a minimum signal level for the audio frame; and
determine that the peak energy level for the audio frame exceeds the minimum signal level for the audio frame by an amount which is below a fourth predetermined energy threshold value.

57. The apparatus as claimed in claim 56, wherein the at least one memory and the computer code configured with the at least one processor to cause the apparatus to determine the minimum signal level for the audio frame is further configured to cause the apparatus to:
determine an energy value for a plurality of consecutive audio samples encompassed within the audio frame;
determine a further energy value of a further plurality of consecutive audio samples within the audio frame, wherein the plurality of consecutive audio samples and the further plurality of consecutive audio samples overlap within the audio frame; and
select the minimum signal level for the audio frame to be the minimum of the energy value and the further energy value.

58. The apparatus as claimed in claim 48, wherein the sample wise suppressor gain function applied to the at least one audio sample is applied to at least one sample of a sub band audio signal of the band limited audio signal.
